(19) United States
(12) Patent Application Publication
(10) Pub. No.: US 2024/0348001 A1
(43) Pub. Date: Oct. 17, 2024

(54) TUNABLE LASER

(71) Applicant: SMART PHOTONICS HOLDING B.V., Eindhoven (NL)

(72) Inventor: Stefanos ANDREOU, Eindhoven (NL)

(21) Appl. No.: 18/752,377

(22) Filed: Jun. 24, 2024

Related U.S. Application Data
(63) Continuation of application No. PCT/EP2022/087767, filed on Dec. 23, 2022.

(30) Foreign Application Priority Data
Dec. 31, 2021 (GB) 2119136.6

(51) Int. Cl. H01S 3/107; H01S 3/063

(52) U.S. Cl. CPC H01S 3/107; H01S 3/063

(57) ABSTRACT

A linear tunable laser comprising: a first tunable resonator, a second tunable resonator, an interferometer, an optical amplifier, and a power splitter. The first tunable resonator comprises a waveguide. The interferometer comprises a plurality of waveguides. At least one of the waveguides of the interferometer is optically connected to the first tunable resonator. The optical amplifier is optically connected to the interferometer. The second tunable resonator comprises a waveguide optically that is connected to the optical amplifier. The power splitter is for outputting light from the linear tunable laser.

### CROSS-REFERENCE TO RELATED APPLICATIONS

This application is a continuation under 35 U.S.C. § 120 of International Application No. PCT/EP2022/087767, filed Dec. 23, 2022 which claims priority to United Kingdom Application No. GB 2119136.6, filed Dec. 31, 2021 under 35 U.S.C. § 119(a). Each of the above-referenced patent applications is incorporated by reference in its entirety.

### BACKGROUND

Tunable lasers are used to produce light of at least one of tunable wavelength or tunable irradiance. This allows the output of light with tuned wavelength and/or irradiance, for example for communications systems and optical systems. Efficient output of light and efficient and broad tuning of the output light can allow more accurate and/or faster optical devices. It is desirable to provide an improved laser.

### BRIEF DESCRIPTION OF THE DRAWINGS

FIGS. 1 to 7 show schematically a plan views of tunable lasers in accordance with examples.

FIG. 8 shows schematically a plan view of a photonic integrated circuit (PIC) in accordance with examples.

FIG. 9 shows schematically a plan view of a device in accordance with examples.

FIG. 10 schematically illustrates a method of manufacturing in accordance with examples.

### DETAILED DESCRIPTION

In examples to be described, a linear tunable laser is configured such that an optical amplifier amplifies light and a tuning element, e.g. tunable resonator or interferometer, tunes at least one of the irradiance or the wavelength of the light output by the tunable laser. In so doing, the tunable laser can e.g. provide light of a chosen wavelength and/or irradiance.

Examples described herein relate to a linear tunable laser. A linear tunable laser comprises a linear optical cavity, in some examples, both the wavelength and intensity of the output light from the linear tunable laser is tunable. In some examples, the linear tunable laser is a component of a semiconductor structure, e.g. a photonic integrated circuit (PIC). The output of light from the linear tunable laser is, for example, for light emitting devices or systems such as those for medical imaging, spectroscopy, telecommunications, optical data transmission and light detection and ranging (LIDAR).

For some examples described herein, the output light of the linear tunable laser has a single wavelength intensity-peak that is tunable over a range of, e.g. more than 35 nanometres. In some examples, a single intensity-peak is achieved by the superposition of three optical filters: the first tunable resonator, the second tunable resonator and the interferometer. In other examples, a single intensity-peak is achieved by the superposition of four optical filters: the first tunable resonator, the second tunable resonator, the first interferometer and the second interferometer. In further examples, the single intensity-peak and wavelength tuning are achieved by the superposition of two optical filters: the first tunable resonator and the interferometer, and tuning of the irradiance of the output light is achieved by the second tunable resonator. In some examples, the single intensity-peak and wavelength tuning are achieved by the superposition of two optical filters: the first tunable resonator and the first interferometer, and tuning of the irradiance of the output light is achieved by the second tunable resonator and the second interferometer.

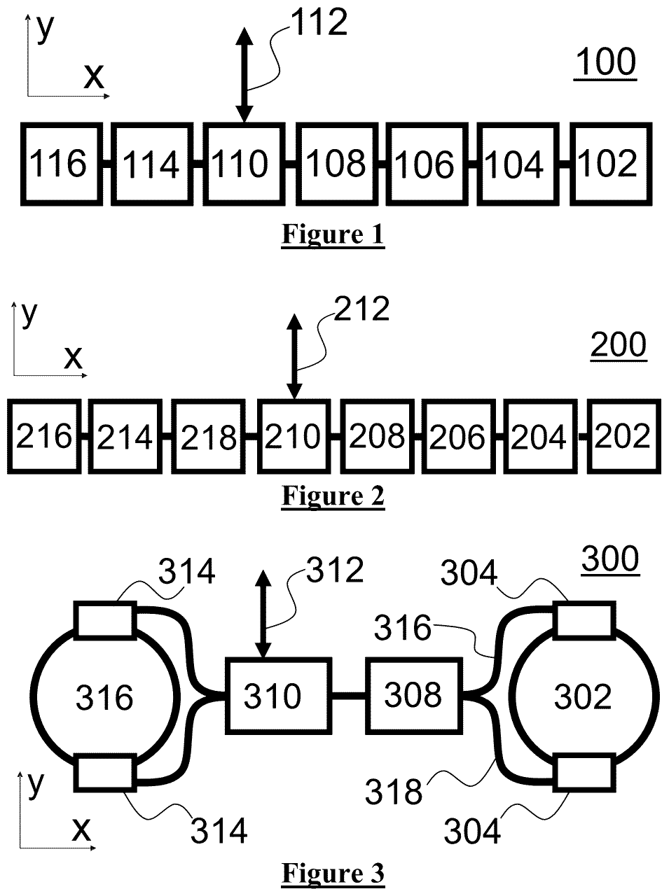

By way of a general introduction to the examples described herein, and with reference to FIGS. 1, a linear tunable laser 100 comprises a first tunable resonator 102 comprising a waveguide; an interferometer 106 comprising a plurality of waveguides, at least one of the waveguides optically connected to the first tunable resonator; an optical amplifier 108 optically connected to the interferometer; a second tunable resonator 116 comprising a waveguide optically connected to the optical amplifier; and a power splitter 110 for the output of light 112 from the linear tunable laser. The linear tunable laser is configured for the output of light 112. In some examples an optical connection between the first tunable resonator 102 and the interferometer comprises a power splitter 104. In some examples an optical connection between the second tunable resonator 116 and the optical amplifier 108 comprises a power splitter 114. Some such examples are illustrated by FIG. 1, and corresponding reference numerals are given earlier in this paragraph. In some examples, the linear tunable laser comprises a linear cavity, the linear cavity comprising the first tunable resonator, the interferometer, the optical amplifier, the second tunable resonator and the power splitter. A linear cavity e.g. at least one of reduces the footprint of the linear tunable laser compared to other cavity configurations such as a ring cavity or achieves more efficient filtering of the lasing mode. In some examples, the free spectral range of the first tunable resonator is different to the free spectral range of the second tunable resonator, in other examples, the free spectral range of the first tunable resonator is the same as the free spectral range of the second tunable resonator. In some examples, the linear tunable laser comprises at least one of an optical input; or an optical output. In some examples, the power splitter is a first power splitter and the linear tunable laser comprises a second power splitter for coupling light into the linear tunable laser.

In some examples, by utilising wavelength dependant interference, the interferometer is configured as a spectral filter and has the effect of suppressing undesired wavelengths of light. In some examples, the interferometer is modulated to allow the tuning of the wavelength of light output from the linear tunable laser. In some examples, at least one of the first tunable resonator or the second tunable resonator is configured as a spectral filter and has the effect of suppressing undesired wavelengths of light. In some examples, spectral filtering of the output light is desirable for applications, e.g. optical communications. This can reduce the need for a further optical component for wavelength tuning, which e.g. simplifies manufacture of a device comprising the linear tunable laser, reduces the footprint of and/or reduces the cost of producing a device comprising the laser.

In some examples, by utilising constructive interference or destructive interference, at least one of the interferometer, the first tunable resonator or the second tunable resonator is configured as an intensity modulator and allows modulation of the irradiance of light output from the linear tunable laser. Output intensity modulation is desirable for applications, e.g. optical coherence tomography or LIDAR. This can reduce the need for a further optical component for output irradiance tuning, which e.g. simplifies manufacture of a device comprising the linear tunable laser, reduces the footprint of and/or reduces the cost of producing a device comprising the laser.

A laser emits light produced by optical amplification. In some examples, light emitted from a laser is spatially coherent and temporally coherent.

A tunable resonator is for the formation of standing waves of light due to interference. In some examples a tunable resonator comprises a plurality of mirrors and separated by a distance such that a standing wave occurs when light is injected into the resonator. In some examples a resonator comprises a ring along the circumference of which light propagates, the circumference of the ring such that a standing wave occurs when light is injected into the resonator. Other tunable resonators are envisaged such as a plane parallel resonator, a concentric resonator, a confocal resonator, a disc resonator, a toroidal resonator, or a hemispherical resonator. A tunable resonator is tuned by tuning the optical path length of the resonator, which in turn tunes the wavelength of the standing wave formed in the resonator. In some examples, tuning of the wavelength of the standing wave is achieved by changing the length, circumference and/or refractive index of the tunable resonator. The refractive index of the tunable resonator is e.g. modulated by an electro-refractive modulator. In some examples tuning is achieved by thermal modulation or carrier injection.

An optical amplifier amplifies the intensity of an optical signal. In some examples, optical amplification is achieved by at least one of stimulated emission or emission due to electron-hole recombination. The wavelength of light amplified by the optical amplifier is e.g. between 10 nanometres and 1 millimetre. Examples of optical amplifiers are: solid-state amplifiers, doped-fibre amplifiers, semiconductor amplifiers, Raman amplifiers, or parametric amplifiers. In some examples, a semiconductor amplifier comprises Indium Gallium Arsenide Phosphide (InGaAsP) or Aluminium Indium Gallium Arsenide (AlInGaAs). Other optical amplifiers are envisaged. A power splitter has at least one light input and splits the light into a plurality of light outputs. In some examples a power splitter is a multimode interferometer (MMI), in other examples, a power splitter is a beam splitter, a partial mirror, a directional coupler, or a prism, other power splitters are envisaged. In some examples the splitting ratio between the optical outputs of the power splitter is 1:1, other ratios are envisaged, e.g. between 1:100 and 100:1.

An interferometer uses interference between a plurality of light beams when the light beams are combined. A phase difference between the light beams produces constructive interference or destructive interference. In some examples the interferometer is a Mach-Zehnder interferometer, such as an asymmetric Mach-Zehnder interferometer. Other example interferometers are a Fizeau interferometer, a Fabry Perot interferometer, a Michelson interferometer, or a Lyot interferometer, other interferometers are envisaged. In some examples, an interferometer comprises an electro-refractive modulator. In some such examples, the electro-refractive modulator is configured to modulate the phase difference between the light beams when they interfere.

A waveguide is for guiding light. Light propagates within a waveguide and is confined within a waveguide due to reflection at the boundaries of the waveguide. A waveguide usually has a refractive index higher than the refractive index of material in contact with the waveguide at the boundaries at which confinement of light is desired. For example, due to this refractive index difference at the boundaries at which confinement of light is desired, total internal reflection takes place when the angle of incidence at these boundaries of the waveguide is greater than the critical angle. In this manner, a waveguide guides the propagation of light. For a particular optical mode to propagate in the waveguide, it is desired that light reflected at the boundaries of the waveguide fulfils the conditions for constructive interference. In some examples, the waveguides is at least one of: an etched ridge waveguide, vertical p-i-n junction or an electro-refractive modulator.

An optical filter transmits or reflects a first wavelength band of a light spectrum with greater irradiance than a second wavelength band of a light spectrum. An optical filter can be a periodic filter, a bandpass filter, a high-pass filter, or a low-pass filter, other filters are envisaged.

An optical connection is achieved in different ways in different examples. In some examples optical connections are achieved with waveguides; however, in other examples, other connections are envisaged, such as free-space propagation, and optical fibre connections. In some examples a tapered waveguide connects components that require different electrical and/or optical properties. In some examples herein, at least one of the optical connections are an optical coupling.

In some examples, the light comprises infrared radiation; in some such examples, the wavelength of the light is tunable between 1530 nanometres and 1565 nanometres. In some examples, such wavelengths are used for telecommunication applications.

A PIC integrates a plurality of photonic functions, for example a laser or a photodiode, other photonic functions are envisaged. In some examples, a PIC is configured for use with at least one of ultraviolet light, visible light, or infrared light. Optical radiation e.g. includes at least one of ultraviolet light, visible light, or infrared light. In some examples, a PIC comprises an electrical circuit. PICs are used for communications devices, biomedical devices and photonic computing, other applications are envisaged.

In examples, such as those of FIG. 1, the linear tunable laser 100 comprises a first tunable resonator 102, a MMI 104, an interferometer 106, an optical amplifier 108, a power splitter 110, an output and/or input of light 112, a MMI 114, and a second tunable resonator 116. Optical connections are indicated by the lines between boxes.

In examples, such as those of FIG. 2, the interferometer 200 is a first interferometer, and the linear tunable laser comprises: a second interferometer 218 comprising a plurality of waveguides, at least one of the waveguides optically connected to the optical amplifier 208 and at least one of the waveguides optically connected to the second tunable resonator 216. Features of these examples are similar to features described above, and will be referred to using the same reference numeral incremented by 200 instead of 100; corresponding descriptions for such features apply here also.

In examples, such as those of FIG. 3, the first tunable resonator 302 is a tunable ring resonator optically connected by two MMIs 304 to a Mach-Zehnder interferometer comprising two waveguides 316 and 318. In some examples, the Mach-Zehnder interferometer is asymmetric, in other examples, the Mach-Zehnder interferometer is symmetric. The second tunable resonator is optically connected to the power splitter by two MMIs 314. In some examples, at least one of the first tunable ring resonator or the second ring resonator comprises a waveguide which forms a ring. In some such examples the waveguide is an electro-refractive modulator. In some examples, the radius of the first tunable resonator is different as the radius of the second tunable resonator, which e.g. allows mode selection; in other examples the radius of the first tuneable ring resonator is the same as the radius of the second ring resonator. Features of these examples are similar to features described above, and will be referred to using the same reference numeral incremented by 300 instead of 100 or 200; corresponding descriptions for such features apply here also.

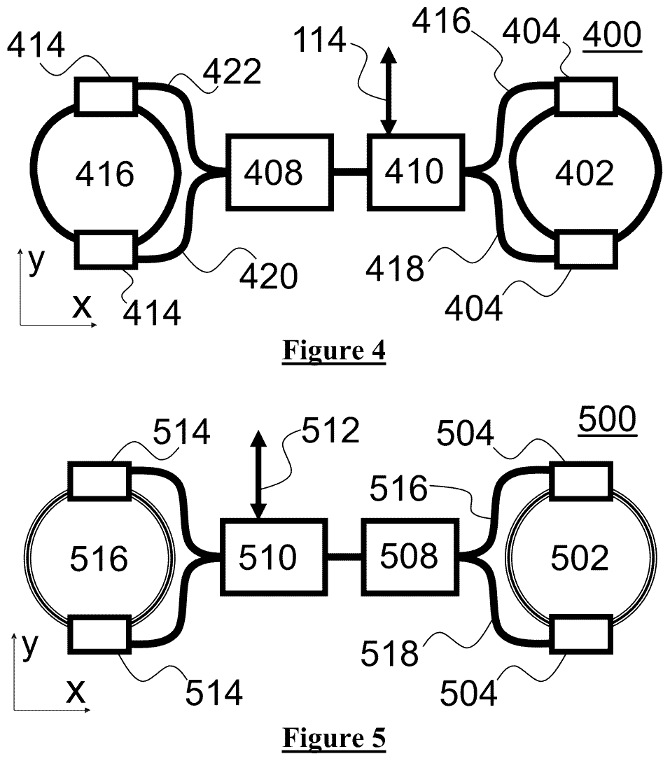

In examples, such as those of FIG. 4, the second tunable resonator 416 is connected by two MMIs 414 to a Mach-Zehnder interferometer comprising two waveguides 420 and 422. In some such examples at least one of the waveguides of the Mach Zehnder interferometer is an electro-refractive modulator. In some examples, the Mach-Zehnder interferometer is asymmetric, in other examples, the Mach-Zehnder interferometer is symmetric. In examples of FIG. 4, the waveguides of the first tunable resonator 402 and the second tunable resonator 416 are curved to form a tunable ring resonator but are not circular. In some examples, the first tunable resonator and the first interferometer are configured for tuning the irradiance of light output from the linear tunable laser. In some examples, the second tunable resonator and the second interferometer are configured for tuning the wavelength of light output from the linear tunable laser. Features of these examples are similar to features described above, and will be referred to using the same reference numeral incremented by 400 instead of 100 200, or 300; corresponding descriptions for such features apply here also.

In examples, such as those of FIG. 5, the optical amplifier is a first optical amplifier and the waveguides of the first tunable resonator 502 and the second tunable resonator 516 comprise a second optical amplifier and a third optical amplifier respectively. In some examples this increases the irradiance of the output of the linear tunable laser 500 without needing to increase the size or footprint of the linear tunable laser. Features of these examples are similar to features described above, and will be referred to using the same reference numeral incremented by 500 instead of 100 200, 300 or 400; corresponding descriptions for such features apply here also.

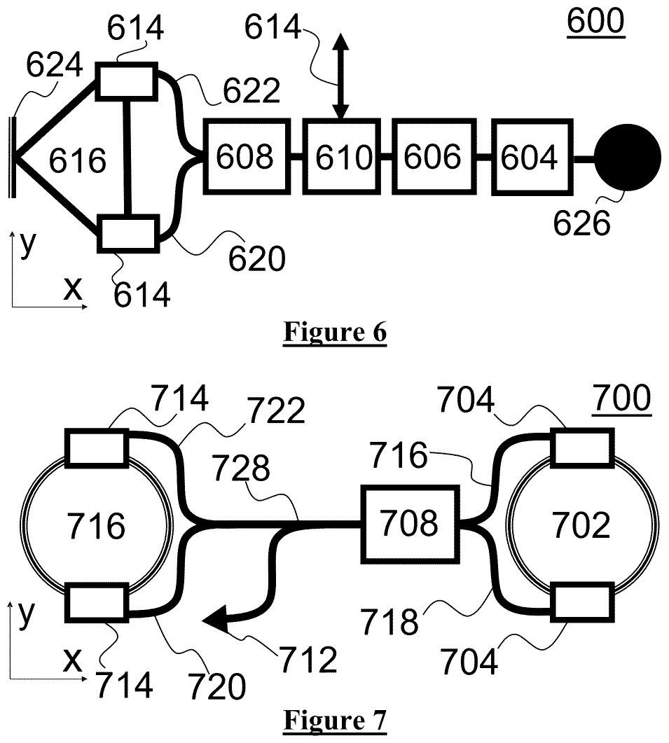

In examples, such as those of FIG. 6, the first tunable resonator is a disc resonator 626 and the second tunable resonator comprises a movable mirror 624. Features of these examples are similar to features described above, and will be referred to using the same reference numeral incremented by 600 instead of 100, 200, 300, 400 or 500; corresponding descriptions for such features apply here also.

In examples, such as those of FIG. 7, the power splitter is a directional coupler 728 formed by an output waveguide 712 being optically connected to the linear tunable laser at the connection between the optical amplifier 708 and the second interferometer 720 and 722. Features of these examples are similar to features described above, and will be referred to using the same reference numeral incremented by 700 instead of 100, 200, 300, 400, 500 or 600; corresponding descriptions for such features apply here also.

Some examples are configured for use in, or integration into, a generic photonic platform, e.g. an Indium Phosphide (InP) platform. In some examples integration into a generic photonic platform simplifies combination of the linear tunable laser with one or more components of the PIC which e.g. allows simpler, cheaper and/or quicker fabrication of the PIC.

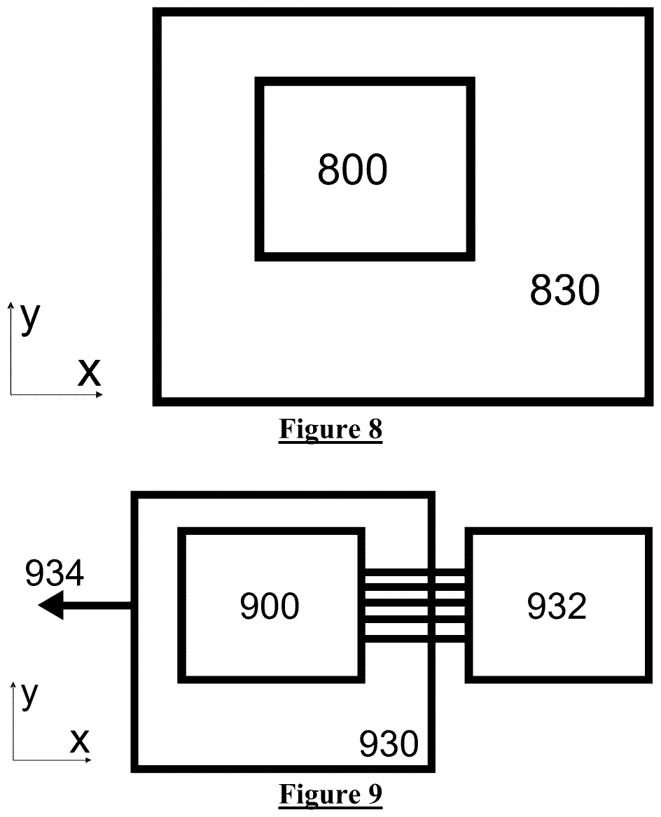

In examples, such as those of FIG. 8, the linear tunable laser 800 is on a substrate 830, and the substrate is a monolith for a PIC. In other examples, the substrate is not a monolith for a PIC. In some examples, the linear tunable laser is integrated into a PIC.

In examples, such as those of FIG. 9, a photonic device comprises a PIC 930, the PIC comprising the previously described tunable linear laser 900, an output for light 934, and an electrical controller 932. In some examples, the controller 932 is configured to tune at least one of the peak wavelength of light output from the linear tunable laser, or the irradiance of the peak wavelength of light output from the linear tunable laser. In some examples, the PIC comprises electrical circuitry which allows external control of components of the PIC by appropriate electrical connections to electrodes or other electrical contacts on the PIC.

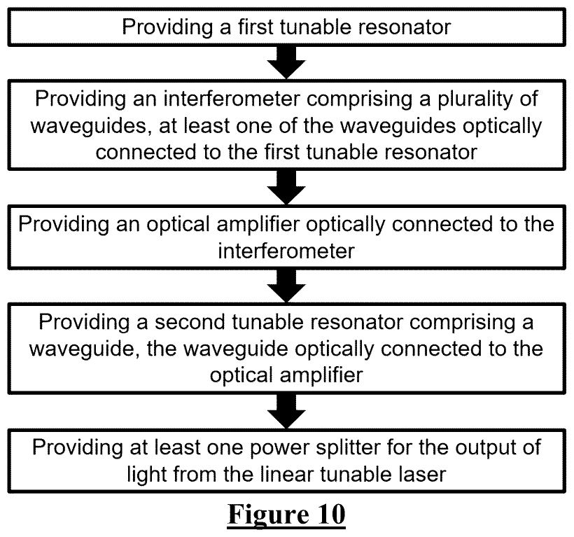

FIG. 10 schematically illustrates a method of manufacturing a linear tunable laser in accordance with examples described previously, comprising: providing a first tunable resonator; providing an interferometer comprising a plurality of waveguides, at least one of the waveguides optically connected to the first tunable resonator; providing an optical amplifier optically connected to the interferometer; providing a second tunable resonator comprising a waveguide, the waveguide optically connected to the optical amplifier; and providing at least one power splitter for the output of light from the linear tunable laser. As the skilled person will appreciate, one or more of the components of the linear tunable laser can be provided by forming them during a manufacture process, using known techniques such as: metalorganic vapour-phase epitaxy (MOVPE), surface passivation, photolithography, ion implantation, etching, dry etching ion etching, wet etching, buffered oxide etching, plasma ashing, plasma etching, thermal treatment, annealing, thermal oxidation, chemical vapor deposition, atomic layer deposition, physical vapor deposition, molecular beam epitaxy, laser lift-off, electrochemical deposition, electroplating, or chemical-mechanical polishing. In some examples etching techniques are used to remove portions of material, as part of patterning, as the skilled person will appreciate.

The above examples are to be understood as illustrative examples of the invention. Further examples of the invention are envisaged. For example, at least one of the waveguides, optical amplifier, tunable resonators, interferometer, semiconductors or substrates, described herein comprise at least one of Indium Phosphide (InP), Gallium Arsenide (GaAs), Gallium Antimonide (GaSb), Gallium Nitride (GaN), Indium Gallium Arsenide (InGaAs), Indium Aluminium Arsenide (InAlAs), Indium Aluminium Gallium Arsenide (InAlGaAs), Indium Gallium Arsenide Phosphide (InGaAsP), Silicon (Si), Silicon Nitride (Si₃N₄), Silicon Oxide (SiO₂), or Lithium Niobate (LiNbO₃); however, other semiconductor, and photonic materials are envisaged.

It is to be understood that any feature described in relation to any one example may be used alone, or in combination with other features described, and may also be used in combination with one or more features of any other of the example, or any combination of any other of the examples. Furthermore, equivalents and modifications not described above may also be employed without departing from the scope of the accompanying claims.

What is claimed is:

1. A linear tunable laser comprising:
a first tunable resonator comprising a waveguide;
an interferometer comprising a plurality of waveguides, at least one of the waveguides optically connected to the first tunable resonator;
an optical amplifier optically connected to the interferometer;
a second tunable resonator comprising a waveguide optically connected to the optical amplifier; and
a power splitter for outputting light from the linear tunable laser.

2. The linear tunable laser of claim 1, wherein at least one of the first tunable resonator, the second tunable resonator, or the interferometer is configured for tuning the wavelength of light for the power splitter to output.

3. The linear tunable laser of claim 1, wherein at least one of the first tunable resonator, the second tunable resonator, or the interferometer is configured for tuning the irradiance of light for the power splitter to output.

4. The linear tunable laser of claim 1, wherein at least one of the waveguide of the first tunable resonator or the waveguide of the second tunable resonator is curved.

5. The linear tunable laser of claim 1, wherein at least one of the first tunable resonator or the second tunable resonator is respectively a tunable ring resonator.

6. The linear tunable laser of claim 1, wherein the first tunable resonator is a first tunable ring resonator and the second tunable resonator is a second tunable ring resonator, wherein the radius of the first tunable ring resonator is different from the radius of the second tunable ring resonator.

7. The linear tunable laser of claim 1, wherein at least one of the first tunable resonator, the second tunable resonator, or the interferometer respectively comprises an electro-refractive modulator.

8. The linear tunable laser of claim 1, wherein the interferometer is at least one of: a Mach-Zehnder interferometer, or an asymmetric Mach-Zehnder interferometer.

9. The linear tunable laser of claim 1, wherein the optical amplifier is a first optical amplifier and at least one of the first tunable resonator or the second tunable resonator respectively comprises a second optical amplifier.

10. The linear tunable laser of claim 1, wherein the interferometer is a first interferometer, and the linear tunable laser comprises: a second interferometer comprising a plurality of waveguides with at least one of the waveguides optically connected to the optical amplifier and at least one of the waveguides optically connected to the second tunable resonator.

11. The linear tunable laser of claim 10, wherein the first tunable resonator and the first interferometer are configured for tuning the irradiance of the peak irradiance of light for the power splitter to output, and the second tunable resonator and the second interferometer are configured for tuning the wavelength of light for the power splitter to output.

12. The linear tunable laser of claim 1, wherein at least one optical connection or the power splitter respectively comprises at least one of a multi-mode interferometer or a directional coupler.

13. The linear tunable laser of claim 1, wherein the free spectral range of the first tunable resonator is different to the free spectral range of the second tunable resonator.

14. The linear tunable laser of claim 1, wherein at least one of: the first tunable resonator, the second tunable resonator, or the optical amplifier comprises Indium phosphide (InP).

15. The linear tunable laser of claim 1, wherein the power splitter is a first power splitter and the linear tunable laser comprises a second power splitter for coupling light into the linear tunable laser.

16. The linear tunable laser of claim 1, wherein the linear tunable laser is on a monolith for a photonic integrated circuit.

17. A photonic integrated circuit comprising:
a linear tunable laser comprising:
a first tunable resonator comprising a waveguide;
an interferometer comprising a plurality of waveguides, at least one of the waveguides optically connected to the first tunable resonator;
an optical amplifier optically connected to the interferometer;
a second tunable resonator comprising a waveguide optically connected to the optical amplifier; and
a power splitter for outputting light from the linear tunable laser.

18. A device comprising:
a photonic integrated circuit comprising:
a first tunable resonator comprising a waveguide;
an interferometer comprising a plurality of waveguides, at least one of the waveguides optically connected to the first tunable resonator;
an optical amplifier optically connected to the interferometer;
a second tunable resonator comprising a waveguide optically connected to the optical amplifier; and
a power splitter for outputting light from the linear tunable laser.

19. The device of claim 18, comprising a controller configured to tune at least one of the peak wavelength of light output from the linear tunable laser, or the irradiance of the peak wavelength of light output from the linear tunable laser.

20. A method of manufacturing a linear tunable laser, the method comprising:
providing a first tunable resonator comprising a waveguide;
providing an interferometer comprising a plurality of waveguides, at least one of the waveguides optically connected to the first tunable resonator;
providing an optical amplifier optically connected to the interferometer;
providing a second tunable resonator comprising a waveguide, the waveguide optically connected to the optical amplifier; and
providing at least one power splitter for outputting light from the linear tunable laser.
